(19) United States
(12) Patent Application Publication
(10) Pub. No.: US 2026/0323819 A1
(43) Pub. Date: Oct. 15, 2026

(54) WIRING SUBSTRATE AND METHOD FOR MANUFACTURING WIRING SUBSTRATE

(71) Applicant: IBIDEN CO., LTD., Gifu (JP)

(72) Inventor: Kosei OSADA, Gifu (JP)

(73) Assignee: IBIDEN CO., LTD., Gifu (JP)

(21) Appl. No.: 19/292,315

(22) Filed: Aug. 6, 2025

(30) Foreign Application Priority Data
Aug. 8, 2024 (JP) 2024-132084

(51) Int. Cl. H05K 1/02; H05K 3/18

(52) U.S. Cl. CPC H05K 1/0296; H05K 3/184

(57) ABSTRACT

A wiring substrate includes an insulating layer, and a conductor layer laminated on a surface of the insulating layer and including wiring patterns such that the wiring patterns are formed in parallel. The wiring patterns include wiring patterns having an inter-pattern distance of 3 μm or less such that at least one of the wiring patterns having the inter-pattern distance of 3 μm or less has a width at an end portion on the insulating layer side that is smaller than a width at a central portion in the lamination direction of the insulating layer and the conductor layer.

### CROSS-REFERENCE TO RELATED APPLICATIONS

The present application is based upon and claims the benefit of priority to Japanese Patent Application No. 2024-132084, filed Aug. 8, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2020-136646 describes a printed wiring board. The entire contents of this publication are incorporated herein by reference.

### SUMMARY OF THE INVENTION

According to one aspect of the present invention, a wiring substrate includes an insulating layer, and a conductor layer laminated on a surface of the insulating layer and including wiring patterns such that the wiring patterns are formed in parallel. The wiring patterns include wiring patterns having an inter-pattern distance of 3 μm or less such that at least one of the wiring patterns having the inter-pattern distance of 3 μm or less has a width at an end portion on the insulating layer side that is smaller than a width at a central portion in the lamination direction of the insulating layer and the conductor layer.

According to another aspect of the present invention, a method for manufacturing a wiring substrate includes forming an insulating layer, and forming wiring patterns such that the wiring patterns are formed in parallel on a surface of the insulating layer. The forming of the wiring patterns includes forming resist walls in parallel on the surface of the insulating layer, and forming a plating film between the resist walls in parallel, and the forming of the resist walls includes forming at least one resist wall having a width at an end portion on an insulating layer side in the height direction of each of the resist walls such that the width at the end portion is greater than a width at a central portion in the height direction.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view partially illustrating an example of a wiring substrate according to an embodiment of the present invention;

FIG. 2A is a cross-sectional perspective view of wiring patterns of FIG. 1;

FIG. 2B is an enlarged cross-sectional view of a portion (IIB) of FIG. 1;

FIG. 3 is a cross-sectional view illustrating an example of a wiring substrate according to a first embodiment of the present invention;

FIG. 4 is a cross-sectional view illustrating an example of a wiring substrate according to a second embodiment of the present invention;

FIG. 5A is a cross-sectional view illustrating an example of a method for manufacturing a wiring substrate according to an embodiment of the present invention;

FIG. 5B is a cross-sectional view illustrating an example of a method for manufacturing a wiring substrate according to an embodiment of the present invention;

FIG. 5C is a cross-sectional view illustrating an example of a method for manufacturing a wiring substrate according to an embodiment of the present invention;

FIG. 5D is a cross-sectional view illustrating an example of a method for manufacturing a wiring substrate according to an embodiment of the present invention;

FIG. 5E is a cross-sectional perspective view illustrating an example of a method for manufacturing a wiring substrate according to an embodiment of the present invention;

FIG. 5F is a cross-sectional view illustrating an example of a method for manufacturing a wiring substrate according to an embodiment of the present invention;

FIG. 5G is a cross-sectional view illustrating an example of a method for manufacturing a wiring substrate according to an embodiment of the present invention;

FIG. 5H is a cross-sectional perspective view illustrating an example of a method for manufacturing a wiring substrate according to an embodiment of the present invention;

FIG. 5I is a cross-sectional view illustrating an example of a method for manufacturing a wiring substrate according to an embodiment of the present invention;

FIG. 5J is a cross-sectional view illustrating an example of a method for manufacturing a wiring substrate according to an embodiment of the present invention;

FIG. 5K is a cross-sectional view illustrating an example of a method for manufacturing a wiring substrate according to an embodiment of the present invention; and

FIG. 5L is a cross-sectional view illustrating an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

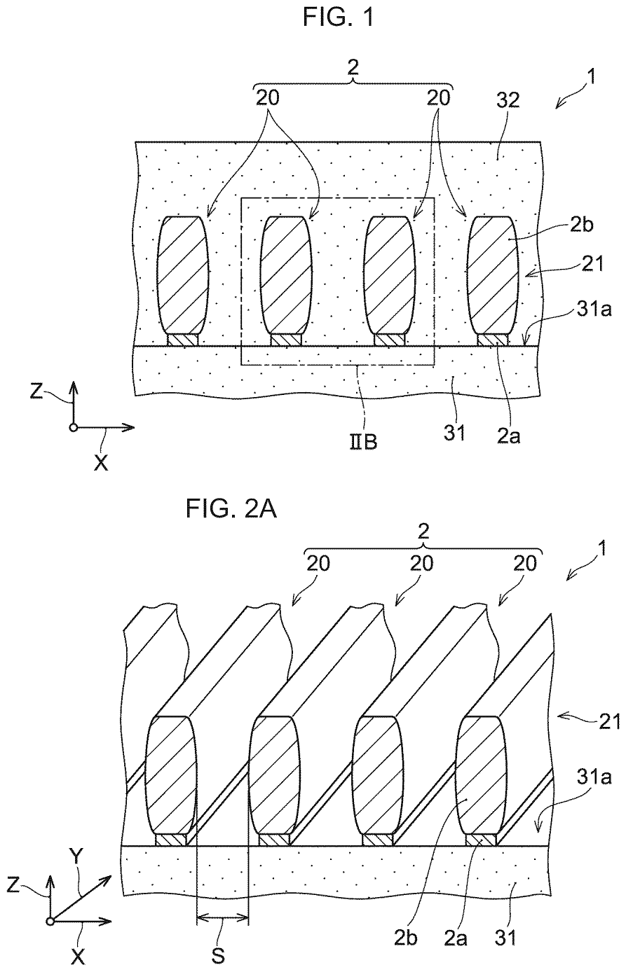

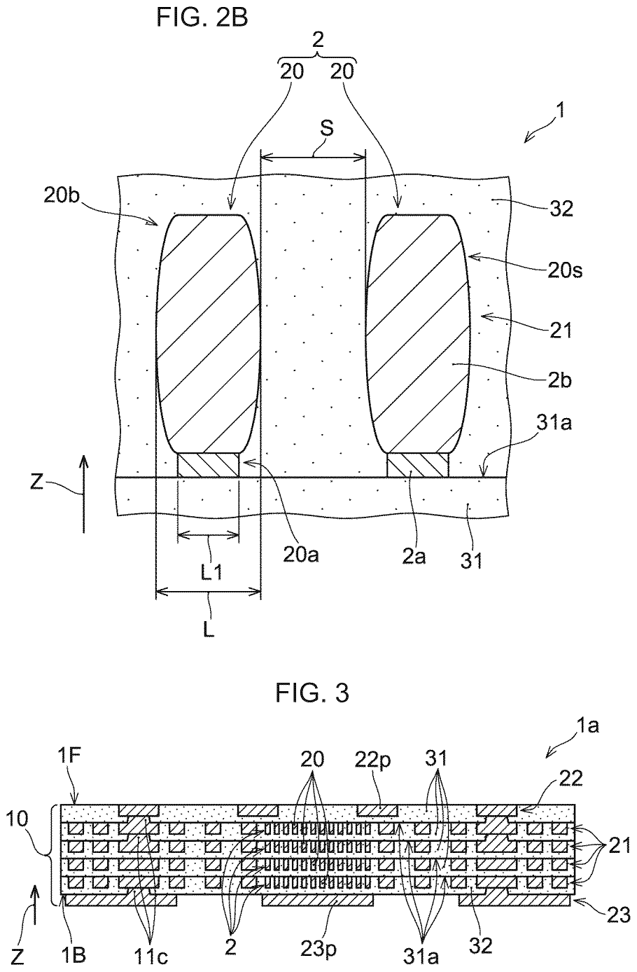

A wiring substrate according to an embodiment of the present invention is described with reference to the drawings. FIG. 1 illustrates a cross-sectional view of a portion of a wiring substrate 1, which is an example of the wiring substrate for the embodiment. FIG. 2A illustrates a cross-sectional perspective view of wiring patterns of the wiring substrate 1 of FIG. 1, and FIG. 2B illustrates an enlarged view of a portion (IIB) in FIG. 1. The wiring substrate illustrated in the drawings referenced in the following description is merely an example of the wiring substrate of the embodiment. A laminated structure of the wiring substrate of the embodiment is not limited to the laminated structure of the wiring substrate illustrated in the drawings, and the number of conductor layers and the number of insulating layers included in the wiring substrate of the embodiment are not limited to the number of conductor layers and the number of insulating layers included in the wiring substrate illustrated in the drawings. The wiring substrate of the embodiment may include, in addition to the insulating layers and conductor layers included in the wiring substrate illustrated in the drawings, any number of insulating layers and conductor layers, and it is also possible that all of the insulating layers and conductor layers included in the wiring substrate illustrated in the drawings are not included. In the drawings to be referenced in the following description, in order to facilitate understanding of the embodiment to be described, a specific portion may be depicted in an enlarged manner. Therefore, it may be possible that structural elements are not depicted in precise proportions in terms of size or length relative to each other.

### Structure of Wiring Patterns in Wiring Substrate

As illustrated in FIGS. 1 to 2B, the wiring substrate 1 includes an insulating layer 31 (first insulating layer) and a conductor layer 21 laminated on a surface (31a) of the insulating layer 31. The wiring substrate 1 in FIG. 1 further includes an insulating layer 32 (second insulating layer). The insulating layer 32 is laminated on the insulating layer 31 and covers the surface (31a) of the insulating layer 31 and the conductor layer 21. In FIG. 2A, illustration of the insulating layer 32 is omitted so that structure of multiple wiring patterns 2 can be easily understood.

The conductor layer 21 includes the multiple wiring patterns 2. As illustrated in FIG. 2A, each wiring pattern 20 of the multiple wiring patterns 2 is formed in parallel in a direction (X direction) that is substantially perpendicular to a direction (Y direction) in which each wiring pattern 20 extends. That is, each wiring pattern 20 of the multiple wiring patterns 2 extends in the Y direction along adjacent other wiring patterns 20, and is formed with a distance (S) from the adjacent other wiring patterns 20 in the X direction. As illustrated in FIGS. 1 and 2B, spaces between the multiple wiring patterns 2, that is, between the wiring patterns 20, are filled with the insulating layer 32.

In the description of the wiring substrate 1 illustrated in FIGS. 1 to 2B, in a lamination direction of the insulating layer 31 and the insulating layer 32, the insulating layer 32 side is also referred to as an “upper side” or simply “upper,” and the insulating layer 31 side is also referred to as a “lower side” or simply “lower.” In other words, the insulating layer 32 is an upper insulating layer with respect to the insulating layer 31, and the insulating layer 31 is a lower insulating layer with respect to the insulating layer 32. Further, the lamination direction of the insulating layer 31 and the insulating layer 32, that is, a thickness direction of the wiring substrate 1, is a thickness direction of the multiple wiring patterns 2 (or a height direction of each wiring pattern 20) and is also referred to as a “Z direction.”

In one example, the wiring substrate 1 of the embodiment has a rectangular shape in a plan view, with each side having a length of 80 μm or more and 240 μm or less. The wiring substrate of the embodiment can have a planar shape of such a size. By using direct imaging exposure described later, each conductor pattern of the conductor layer 21 can be formed relatively easily. The term “plan view” means viewing an object along the Z direction.

Each wiring pattern 20 of the multiple wiring patterns 2 can be a conductor pattern designed and used to apply a voltage, conduct a current, supply power, or transmit an electrical signal from any position to any other different position in the wiring substrate 1 in a plan view. However, the functions of each wiring pattern 20 are not limited to these.

In the wiring substrate 1 in the example illustrated in FIGS. 1 to 2B, the conductor layer 21 is formed of a metal film (2a) in contact with the surface (31a) of the insulating layer 31 and a plating film (2b) in contact with the metal film (2a). Therefore, each wiring pattern 20 of the multiple wiring patterns 2 is also composed of the metal film (2a) and the plating film (2b). In the wiring substrate of the embodiment, the conductor layer 21 and each wiring pattern 20 do not need to be composed of two laminated conductor films as illustrated in FIG. 1 and the like, and may be composed of a single conductor film.

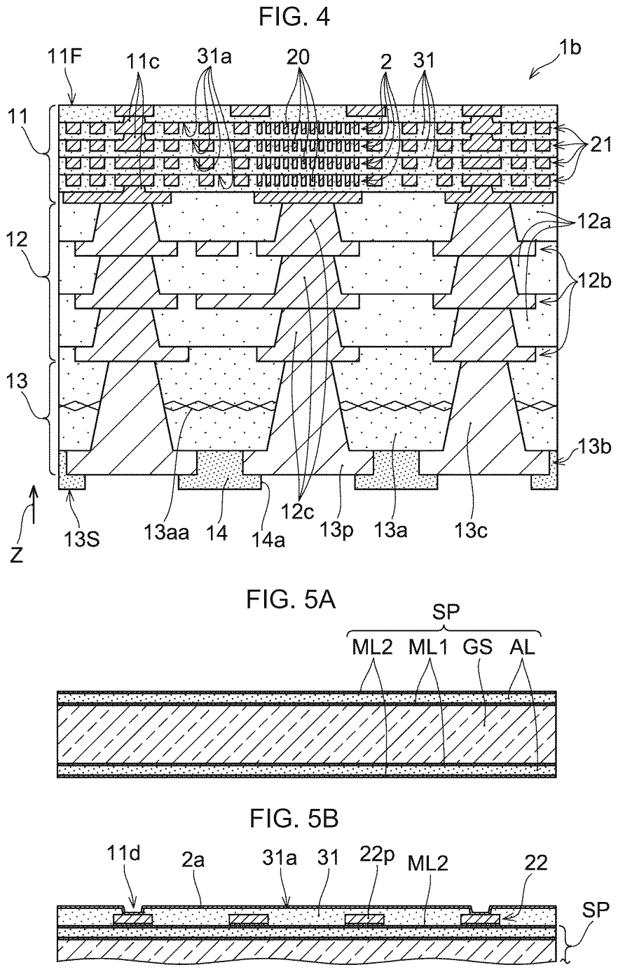

In the wiring substrate of the embodiment, as illustrated in FIGS. 3 and 4 to be referenced later, the conductor layer 21 may include multiple wiring patterns 2 formed of more than four wiring patterns 20. A conductor layer, such as the conductor layer 21, included in the wiring substrate of the embodiment, can include multiple wiring patterns formed of any number of two or more individual wiring patterns. In this case, each of the two or more wiring patterns extends along adjacent other wiring patterns, and is formed in parallel with a distance from the adjacent other wiring patterns in a direction substantially perpendicular to the direction in which each wiring pattern extends.

The insulating layer 31 and the insulating layer 32 are primarily formed of any insulating resin. Examples of insulating resins used in the formation of the insulating layer 31 and the insulating layer 32 include thermosetting resins such as epoxy resin, bismaleimide triazine resin (BT resin), or phenolic resin, as well as thermoplastic resins such as fluorine resin, liquid crystal polymer (LCP), fluorinated ethylene (PTFE) resin, polyester (PE) resin, and modified polyimide (MPI) resin. The insulating layer 31 and the insulating layer 32 may each further contain a filler made of, for example, silicon oxide, alumina, or mullite. The resins listed above are merely examples of materials capable of forming the insulating layer 31 and the insulating layer 32. The insulating layer 31 and the insulating layer 32 can be formed of any material capable of providing insulation to the conductor layer 21 while supporting or covering the conductor layer 21.

The conductor layer 21 is formed of any metal having appropriate conductivity. For example, copper, nickel, and the like can be used as constituent materials of the conductor layer 21. However, the material of the conductor layer 21 is not limited to these metals. In the example of FIG. 1 and the like, as described above, the conductor layer 21 has a two-layer structure including the metal film (2a) and the plating film (2b). The metal film (2a) is, for example, a plating film formed by electroless plating or a sputtering film formed by sputtering. On the other hand, the plating film (2b) is, for example, a metal film formed by electrolytic plating using the metal film (2a) as a power feeding layer. The plating film (2b) is preferably formed by pattern plating using a plating resist with appropriate opening patterns. For example, it is also possible that, different from the example illustrated in FIG. 1 and the like, the conductor layer 21 is composed of only one metal film formed by pattern plating through electroless plating.

In the wiring substrate 1 of the embodiment, a minimum value of the distance (S) between the wiring patterns 20 included in the multiple wiring patterns 2 is 3 μm or less. Further, the wiring patterns 20 included in the multiple wiring patterns 2 may have a minimum width (L) of 3 μm or less. That is, the multiple wiring patterns 2 may be multiple wiring patterns designed with a fine wiring rule of (3 μm)/(3 μm) or less for a wiring rule represented by L/S (line and space) using a minimum wiring width (L) and a minimum inter-wiring distance (S). In other words, the multiple wiring patterns 2 include at least two wiring patterns 20 adjacent to each other with a distance of 3 μm or less, and may further include a wiring pattern 20 having a width of 3 μm or less. Therefore, the wiring substrate 1 of the embodiment can include multiple wirings formed at an extremely fine pitch compared to a wiring pitch level that can be achieved for wirings in a wiring substrate designed or manufactured at the time of the present disclosure.

Further, the wiring patterns 20 of the multiple wiring patterns 2 may have a minimum width (L) of 1 μm or more and a minimum inter-pattern distance (S) of 1 μm or more. That is, the multiple wiring patterns 2 include at least two wiring patterns 20 adjacent to each other with a distance of 1 μm or more and 3 μm or less, and may include a wiring pattern 20 having a width of 1 μm or more and 3 μm or less.

In the description of the wiring substrate of the embodiment, the “width” of each wiring pattern 20 included in the multiple wiring patterns 2 is a largest width at any position between an upper end and a lower end of the wiring pattern 20 in the thickness direction (Z direction) of the multiple wiring patterns 2. For example, the width of each wiring pattern 20 may be a width of the wiring pattern 20 at its center in the Z direction. When each wiring pattern 20 is composed of the metal film (2a) and the plating film (2b) as in the example of FIG. 1, the width of each wiring pattern 20 may be the width of the wiring pattern 20 at a center of the plating film (2b) in the Z direction.

On the other hand, in the description of the wiring substrate of the embodiment, the “inter-pattern distance” of the individual wiring patterns 20 of the multiple wiring patterns 2 is a smallest inter-pattern distance of the wiring patterns 20 at any position between the upper end and the lower end of each wiring pattern 20 in the Z direction. For example, the inter-pattern distance (S) of the wiring patterns 20 may be an inter-pattern distance of the wiring patterns 20 at the center in the Z direction of the wiring patterns 20. When each wiring pattern 20 is composed of the metal film (2a) and the plating film (2b) as in the example of FIG. 1, the inter-pattern distance of the wiring patterns 20 may be an inter-pattern distance of the wiring patterns 20 at the center of the plating film (2b) in the Z direction.

In the wiring substrate 1 of the embodiment, the multiple wiring patterns 2 may further include a wiring pattern 20 having an aspect ratio of 2 or more. That is, a maximum aspect ratio of each wiring pattern 20 is 2 or more. The maximum aspect ratio of each wiring pattern 20 may be 2 or more and 5 or less. That is, the multiple wiring patterns 2 may include a wiring pattern 20 having an aspect ratio of 2 or more and 5 or less. In this way, the multiple wiring patterns 2 can include one or more wiring patterns 20 that, while being fine, have a relatively low conductor resistance by having a large cross section. Therefore, the wiring substrate 1 of the embodiment can include fine wirings having a relatively high conductivity for their fine wiring width.

In the description of the wiring substrate of the embodiment, the aspect ratio of each wiring pattern 20 of the multiple wiring patterns 2 is a ratio of a height of the wiring pattern 20 (a length of the wiring pattern 20 in the Z direction) to the “width” of the wiring pattern 20.

In the wiring substrate 1 of the embodiment, as illustrated in FIG. 2B, each wiring pattern 20 constituting the multiple wiring patterns 2 has a width (L1) at its end portion (20a) on the insulating layer 31 side in the lamination direction (Z direction) of the insulating layer 31 and the conductor layer 21, which is smaller than the width (L) at its central portion in the Z direction. Therefore, when the conductor layer 21 is formed using pattern plating to enable the formation of fine wiring patterns 20 during the manufacturing of the wiring substrate 1 of the embodiment, a resist wall with a large contact area with the underlying metal film (2a) or the insulating layer 31 can be provided.

That is, as a plating resist provided between formation regions of adjacent wiring patterns 20, a resist wall can be provided that contacts the metal film (2a) or the insulating layer 31 over a large area. Even when the width at the central portion of each wiring pattern 20 in the Z direction is small, a resist wall can be formed with a contact area corresponding to a width larger than that width. Therefore, during the formation of the conductor layer 21, it is thought that the plating resist can maintain an appropriate state without undergoing collapse, peeling, or the like. That is, it is thought that multiple wiring patterns 2 formed with extremely fine inter-wiring distances at the central portion can be formed with good yield. Therefore, it is thought that the wiring substrate of the embodiment can include fine wirings and has good productivity.

In particular, in the wiring substrate of the embodiment, as described above, the multiple wiring patterns 2 include at least two wiring patterns 20 adjacent to each other with a distance of 3 μm or less, and may also include a wiring pattern 20 having a width of 3 μm or less. The multiple wiring patterns 2 may further include a wiring pattern 20 having an aspect ratio of 2 or more. In this way, the wiring substrate of the embodiment can include fine wirings having a relatively high conductivity for their fine wiring width, and have good productivity with suppressed defect occurrence during manufacturing.

As in the example of FIGS. 1 to 2B, when each wiring pattern 20 is composed of the metal film (2a) and the plating film (2b) formed by electrolytic plating using the metal film (2a) as a power feeding layer, the “central portion” of the wiring pattern 20 in the Z direction refers to a central portion of the plating film (2b) in the Z direction.

In the wiring substrate of the embodiment, all of the wiring patterns 20 of the multiple wiring patterns 2 may have a width at the end portion (20a) in the Z direction that is smaller than the width at the central portion. Further, it is also possible that only some of the wiring patterns 20 of the multiple wiring patterns 2 have a width at the end portion (20a) in the Z direction that is smaller than the width at the central portion. That is, in the wiring substrate of the embodiment, at least one wiring pattern 20 of the multiple wiring patterns 2 has a width at the end portion (20a) in the Z direction that is smaller than the width at the central portion. As a resist wall provided for the formation of the at least one wiring pattern 20, a resist wall can be provided that is unlikely to collapse or peel off. Therefore, the wiring substrate of the embodiment may include at least one fine wiring having a relatively high conductivity for its fine wiring width, and have good productivity with suppressed defect occurrence during manufacturing.

In the wiring patterns 20 illustrated in FIG. 2B, a ratio of the width (L1) at the end portion (20a) to the width (L) at the central portion is 80% or more and 95% or less. It may be possible that the above-described effect of suppressing collapse or peeling of the resist wall is obtained and that a desired conductivity is also obtained in each wiring pattern 20.

The conductor layer 21 may have a thickness of 2 μm or more and 5 μm or less. It is thought that in each wiring pattern 20, a desired conductivity is obtained, and collapse of the wiring pattern or collapse of the resist wall during the formation of the wiring pattern 20 is unlikely to occur.

As illustrated in FIG. 2B, in the wiring substrate 1, each wiring pattern 20 that has a width at the end portion (20a) in the Z direction smaller than the width at the central portion also has a width at an end portion (20b) on the opposite side with respect to the end portion (20a) in the Z direction that is smaller than the width at the central portion. That is, in the wiring substrate 1 illustrated in FIG. 1 and the like, each wiring pattern 20 that has a width at the end portion (20a) smaller than the width at the central portion has a width at both ends in the Z direction that is smaller than the width at the central portion in the Z direction. Therefore, a side surface (20s) of each wiring pattern 20 that has a width at the end portion (20a) smaller than the width at the central portion is curved so as to bulge outward at the central portion of the wiring pattern 20 in the Z direction. In other words, each portion of the insulating layer 32 (the upper insulating layer relative to the insulating layer 31) between the multiple wiring patterns 2 is constricted at its central portion in the Z direction.

In the wiring substrate 1 illustrated in FIGS. 1 to 2B, the plating film (2b) constituting each wiring pattern 20 can have a relatively smooth side surface. For example, a side surface of a portion constituted by the plating film (2b) of each of the multiple wiring patterns 2 (that is, a portion of the side surface (20s) of each wiring pattern 20) may have an arithmetic mean roughness (Ra) of 0.01 μm or more and 0.2 μm or less as a surface roughness. For example, in high-frequency signal transmission, there may be less degradation in transmission characteristics due to influence of a skin effect.

As described above, the plating film (2b) is preferably formed by pattern plating. Therefore, the side surface of the plating film (2b) can have a surface roughness within the above range, which is smoother than a side surface of a conductor pattern formed using a subtractive method. That is, the side surface of the portion constituted by the plating film (2b) of each of the multiple wiring patterns 2 is not a dissolved surface exposed by etching, but rather a contact surface with the plating resist, which may be a deposited surface of plating metal exposed by removal of the plating resist.

On the other hand, the metal film (2a), as described above, may be an electroless plating film or a sputtering film. In particular, when the metal film (2a) is a sputtering film, the metal film (2a) tends to have a small and uniform thickness. Therefore, in the formation of the conductor layer 21 using a semi-additive method including pattern plating, when a portion of the metal film (2a) that is not covered by the plating film (2b) is removed after pattern plating, it is thought that an exposed portion of the metal film (2a) can be removed in a short time, for example, by quick etching. Therefore, it is thought that the plating film (2b), which has already been formed by electrolytic plating, is unlikely to be affected by this quick etching.

### First Embodiment

FIG. 3 illustrates a cross-sectional view of a wiring substrate (1a), which is an example of a wiring substrate of a first embodiment. Similar to the wiring substrate 1 in FIG. 1, the wiring substrate (1a) includes an insulating layer 31 and a conductor layer 21 laminated on a surface (31a) of the insulating layer 31. The conductor layer 21, similar to the conductor layer 21 of the wiring substrate 1 in FIG. 1, includes multiple wiring patterns 2, and the multiple wiring patterns 2 include wiring patterns 20 formed in parallel. As illustrated in FIG. 3, the wiring substrate (1a) of the present embodiment includes multiple insulating layers 31 and multiple conductor layers 21, with the multiple insulating layers 31 and the multiple conductor layers 21 being alternately laminated. The wiring substrate (1a) in the example of FIG. 3 includes four insulating layers 31 and four conductor layers 21. In FIG. 3, each insulating layer 31 is depicted above a conductor layer 21 formed on the surface (31a) of the insulating layer 31. That is, in FIG. 3, a set of an insulating layer 31 and a conductor layer 21 is depicted as if the insulating layer 31 and the conductor layer 21 in FIG. 1 were rotated 180°.

The wiring substrate (1a) has two surfaces perpendicular to its thickness direction (a first surface (1F) and a second surface (1B) on the opposite side with respect to the first surface (1F)). In addition to the multiple insulating layers 31 and the multiple conductor layers 21, the wiring substrate (1a) includes a conductor layer 22 exposed on the first surface (1F), a conductor layer 23 exposed on the second surface (1B), and an insulating layer 32 exposed on the second surface (1B). In the description of the wiring substrate (1a), the second surface (1B) side of the wiring substrate (1a) is referred to as an “upper side” or simply “upper.”

That is, in the wiring substrate (1a), the conductor layer 22 is provided on the first surface (1F), and toward the second surface (1B), the four insulating layers 31 and the four conductor layers 21 are alternately laminated. Then, the insulating layer 32 is formed to cover the insulating layer 31 and conductor layer 21 closest to the second surface (1B), and the conductor layer 23 is formed on a surface of the insulating layer 32. In this way, the wiring substrate (1a) includes a laminate 10 of the multiple conductor layers and the multiple insulating layers.

Also in the wiring substrate (1a) of FIG. 3, the multiple wiring patterns 2 included in each of the multiple conductor layers 21 include wiring patterns 20 adjacent to each other with a distance of 3 μm or less. The multiple wiring patterns 2 include wiring patterns 20 having a width of 3 μm or less and may also include a wiring pattern 20 having an aspect ratio of 2 or more. Although not explicitly illustrated in FIG. 3, each wiring pattern 20, similar to the wiring patterns 20 illustrated in FIG. 1, has a width at its end portion in a thickness direction (Z direction) of the wiring substrate (1a) that is smaller than a width at its central portion in the Z direction. Each wiring pattern 20 has a width at least at an end portion on the first surface (1F) side in the Z direction that is smaller than the width at the central portion. Therefore, it is thought that the wiring substrate (1a) of the present embodiment can include fine wirings having a relatively high conductivity for their fine wiring width, and have good productivity.

In the wiring substrate (1a), conductor layers facing each other across an insulating layer are connected by via conductors (11c). The conductor layer 22 and the conductor layer 23 each include any conductor patterns. The conductor layer 22 includes conductor pads (22p), and the conductor layer 23 includes conductor pads (23p). An external component (not illustrated) may be mounted and connected to the conductor pads (22p) when the wiring substrate (1a) is used. That is, the conductor pads (22p) can be component mounting pads, and therefore, the wiring substrate (1a) illustrated in FIG. 3 may have a component mounting surface formed by the first surface (1F).

On the other hand, the second surface (1B) of the wiring substrate (1a) is a surface that, when the wiring substrate (1a) is used, can be connected to a motherboard of an electronic device in which the wiring substrate (1a) is used or to a rewiring substrate of a semiconductor package in which the wiring substrate (1a) is used. The wiring substrate (1a) may further include, on the first surface (1F) and/or the second surface (1B), a solder resist (not illustrated) having openings that expose the conductor pads (22p) or the conductor pads (23p).

The insulating layers 31 and the insulating layer 32 of the wiring substrate (1a) are composed of resins similar to the insulating resins described above as constituent materials for the insulating layer 31 and the insulating layer 32 of the wiring substrate 1 in FIG. 1, for example, thermosetting resins such as epoxy resin, BT resin, or phenol resin, or thermoplastic resins such as fluororesin or LCP. The insulating layers 31 and the insulating layer 32 of the wiring substrate (1a) may further contain, for example, a filler made of silicon oxide or the like.

Similar to the conductor layer 21 in the wiring substrate 1 of FIG. 1, the conductor layers (21-23) and the via conductors (11c) are formed of any metal having appropriate conductivity, such as copper or nickel. In FIG. 3, the conductor layers (21-23) are each depicted as having only one layer for clarity, and the via conductors (11c) are also each depicted as having only one layer. However, the conductor layers (21-23) and the via conductors (11c) may each have a multilayer structure including two or more metal films formed using any method, such as sputtering, electrolytic plating or electroless plating.

### Second Embodiment

FIG. 4 illustrates a cross-sectional view of a wiring substrate (1b), which is an example of a wiring substrate of a second embodiment. As illustrated in FIG. 4, the wiring substrate (1b) includes a laminate 11 (first build-up layer) of multiple conductor layers and multiple insulating layers, and a build-up layer 12 (second build-up layer) composed of a laminate of insulating layers (12a) and conductor layers (12b). The wiring substrate (1b) in FIG. 4 further includes a build-up layer 13 (third build-up layer) composed of a laminate of an insulating layer (13a) and a conductor layer (13b).

Similar to the laminate 10 constituting the wiring substrate (1a) in FIG. 3, the laminate 11 includes one or more conductor layers 21 and one or more insulating layers 31. In the example of FIG. 4, the laminate 11 includes four conductor layers 21 and four insulating layers 31. Each conductor layer 21 is formed on a surface (31a) of an insulating layer 31. Similar to the conductor layer 21 of the wiring substrate 1 in FIG. 1, each conductor layer 21 includes multiple wiring patterns 2, and the multiple wiring patterns 2 include wiring patterns 20 formed in parallel.

The wiring substrate (1b) in FIG. 4 has a first surface (11F) corresponding to the first surface (1F) of the wiring substrate (1a) in FIG. 3, and a second surface (13S) on the opposite side with respect to the first surface (11F). In the description of the wiring substrate (1b), the second surface (13S) side of the wiring substrate (1b) is referred to as an “upper side” or simply “upper.” The build-up layer 12 is laminated on the laminate 11. The build-up layer 13 is laminated on the build-up layer 12.

In the wiring substrate (1b) of FIG. 4, the multiple wiring patterns 2 included in each of the multiple conductor layers 21 include wiring patterns 20 adjacent to each other with a distance of 3 μm or less. The multiple wiring patterns 2 include wiring patterns 20 having a width of 3 μm or less and may also include a wiring pattern 20 having an aspect ratio of 2 or more. Although not explicitly illustrated in FIG. 4, each wiring pattern 20, similar to the wiring patterns 20 illustrated in FIG. 1, has a width at its end portion in a thickness direction (Z direction) of the wiring substrate (1b) that is smaller than a width at its central portion in the Z direction. Each wiring pattern 20 has a width at least at an end portion on the first surface (11F) side in the Z direction that is smaller than the width at the central portion. Therefore, it is thought that the wiring substrate (1b) of the present embodiment can include fine wirings having a relatively high conductivity for their fine wiring width, and have good productivity.

In the build-up layer 12, the insulating layers (12a) and the conductor layers (12b) are alternately laminated. In each insulating layer (12a), via conductors (12c) are formed that penetrate the insulating layer (12a) and connect conductor layers facing each other across the insulating layer (12a). The conductor layers (12b) each include desired conductor patterns.

The build-up layer 13 includes the insulating layer (13a) formed on the insulating layer (12a) and conductor layer (12b) of the build-up layer 12, and the conductor layer (13b) formed on a surface of the insulating layer (13a) facing the second surface (13S) side of the wiring substrate (1b). In the insulating layer (13a), via conductors (13c) are formed that penetrate the insulating layer (13a) and connect the conductor layer (13b) to the conductor layer (12b) of the build-up layer 12. The conductor layer (13b) may include desired conductor patterns. The conductor layer (13b) in the example of FIG. 4 includes conductor pads (13p).

The wiring substrate (1b) in the example of FIG. 4 further includes a solder resist layer 14 formed on the second surface (13S). The solder resist layer 14 is formed, for example, using a photosensitive polyimide resin or epoxy resin. Openings (14a) are formed in the solder resist layer 14. The conductor pads (13p) of the conductor layer (13b) are exposed from the openings (14a).

The second surface (13S) of the wiring substrate (1b) is a surface that, when the wiring substrate (1b) is used, is connected to an external component (not illustrated), such as a motherboard of an electronic device in which the wiring substrate (1b) is used. The conductor pads (13p) may be connected to any substrate, electrical component, mechanical component, or the like.

The insulating layers (12a) constituting the build-up layer 12 and the insulating layer (13a) of the build-up layer 13 can be formed using an insulating resin similar to that used for the insulating layers 31. Although not illustrated, the insulating layers (12a) may each contain a core material (reinforcing material) made of glass fiber or aramid fiber. In the example of FIG. 4, the insulating layer (13a) of the build-up layer 13 contains a core material (13aa) made of glass fiber. The insulating layers (12a) and the insulating layer (13a) can further contain an inorganic filler (not illustrated) made of fine particles of silica (SiO2), alumina, mullite, or the like. In the wiring substrate (1b), a thickness of each of the insulating layers (12a) may be greater than a thickness of each of the insulating layers 31, and a thickness of the insulating layer (13a) may be greater than the thickness of each of the insulating layers (12a).

The conductor layers (12b) of the build-up layer 12, the conductor layer (13b) of the build-up layer 13, and the via conductors (12c, 13c) can be formed using any metal, such as copper or nickel, similar to the conductor layers 21 and the via conductors (11c). The conductor layers (12b), the conductor layer (13b), and the via conductors (12c, 13c) may each have, as in the example of FIG. 4, a single-layer structure formed of, for example, only a plating film, or may each have a multilayer structure including two or more metal films formed using any method, such as sputtering or various types of plating. In the wiring substrate (1b), a thickness of each of the conductor layers (12b) may be greater than a thickness of each of the conductor layers 21, and a thickness of the conductor layer (13b) may be greater than the thickness of each of the conductor layers (12b).

In the wiring substrate (1b), when the conductor layers (12b) each include two or more wiring patterns, these wiring patterns may each have a width greater than the width of each of the wiring patterns 20 of the conductor layers 21, and the wiring patterns included in the conductor layers (12b) may have an inter-pattern distance greater than the inter-pattern distance of the wiring patterns 20 of the conductor layers 21. Further, when the conductor layers (12b) and the conductor layer (13b) each include two or more wiring patterns, the wiring patterns included in the conductor layer (13b) may each have a width greater than the width of each of the wiring patterns included in the conductor layers (12b), and the wiring patterns included in the conductor layer (13b) may have an inter-pattern distance greater than the inter-pattern distance of the wiring patterns included in the conductor layers (12b). It may be possible that a large current can be passed through the wiring patterns of the conductor layers (12b) and the conductor layer (13b), and moreover, the conductor layers (12b) and the conductor layer (13b) can be formed easily and inexpensively.

### Method for Manufacturing Wiring Substrate

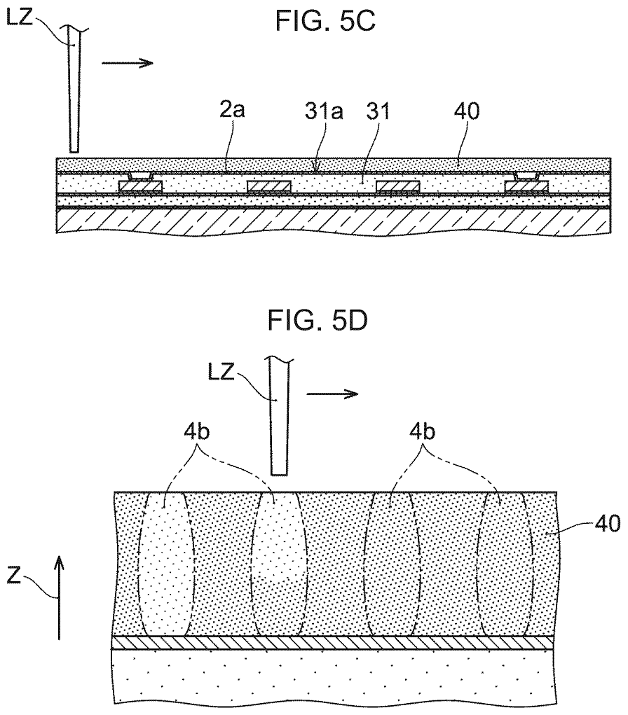

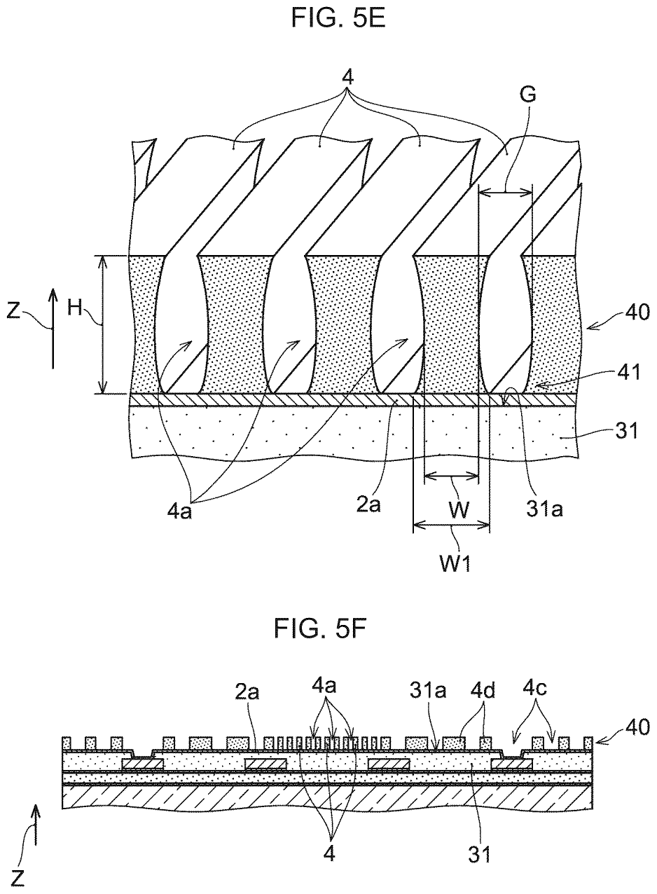

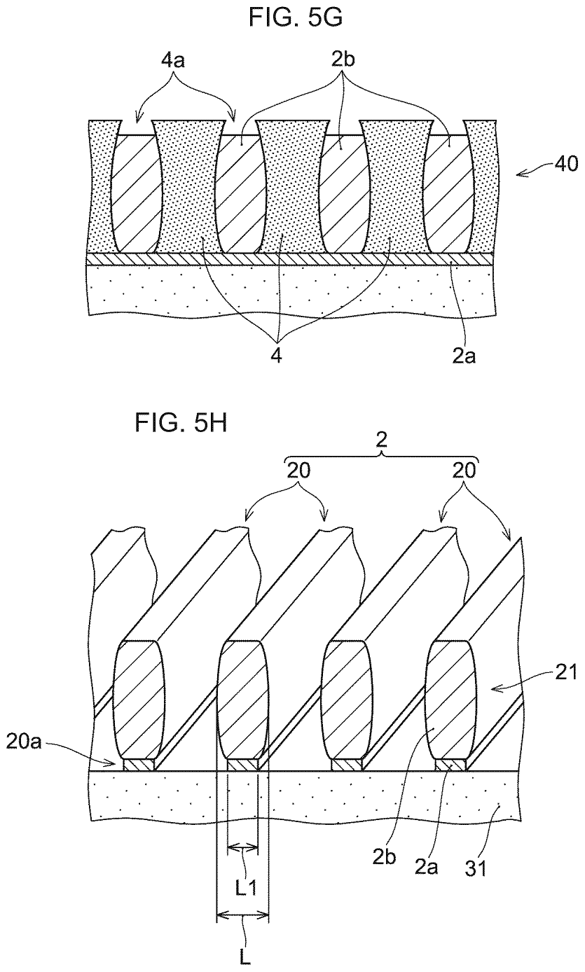

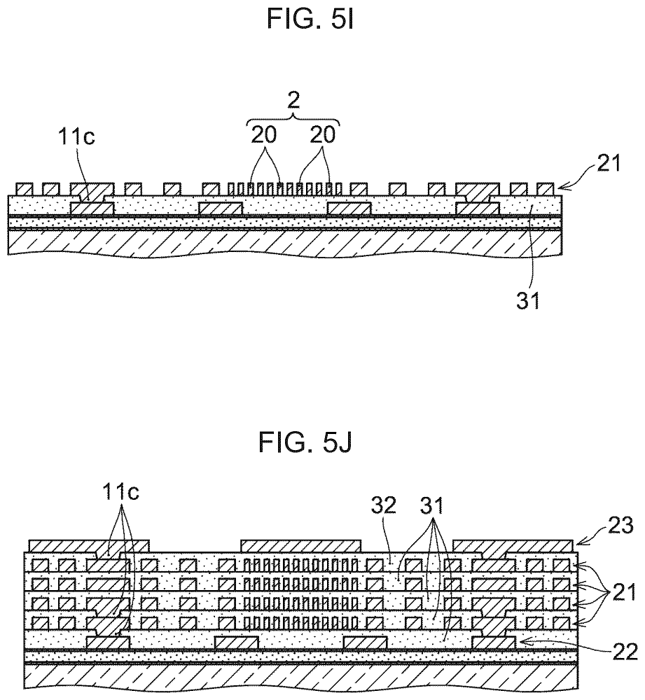

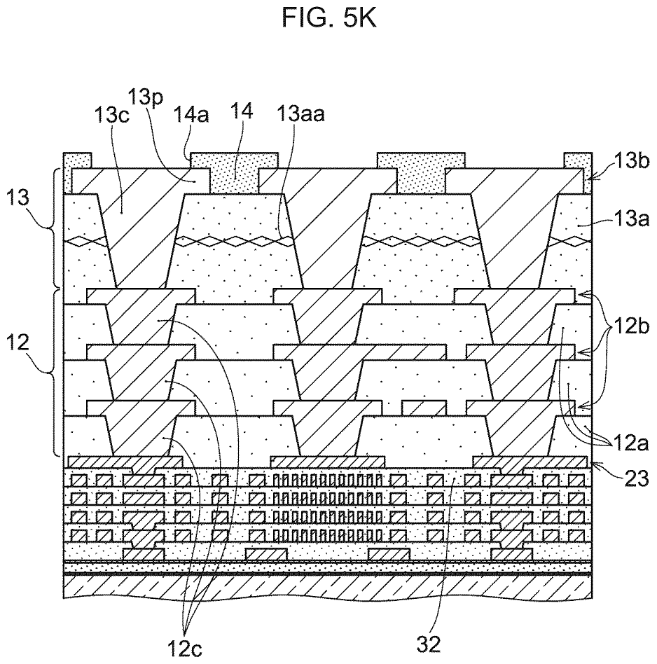

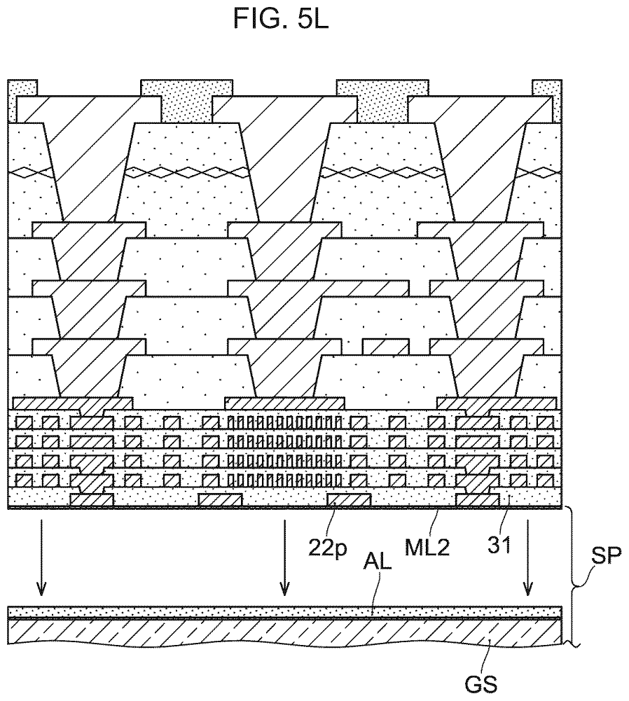

Next, with reference to FIGS. 5A-5L, a method for manufacturing the wiring substrate of the embodiment is described using a case where the wiring substrate (1b) illustrated in FIG. 4 is manufactured as an example. The materials described for the structural elements of the wiring substrates (1, 1a, 1b) of the embodiments can be used as materials for corresponding structural elements in the method for manufacturing the wiring substrate of the embodiment, even when not explicitly stated again in the following description.

As illustrated in FIG. 5A, a support substrate (SP) is prepared, which includes a core layer (GS) and metal film layers (ML1, ML2) laminated on each of two surfaces of the core layer (GS). The core layer (GS) is constituted by, for example, a glass material or a glass epoxy material. The metal film layers (ML1, ML2) are each, for example, a metal layer formed by electroless plating or sputtering using copper, titanium, or the like as a material. The metal film layer (ML1) and the metal film layer (ML2) are bonded together by, for example, an adhesive layer (AL) constituted by an adhesive whose adhesiveness changes when irradiated with light.

In the following description, a side closer to the core layer (GS) of the support substrate (SP) is also referred to as “lower” or “lower side,” and a side farther from the core layer (GS) is also referred to as “upper” or “upper side.” Therefore, of each of the elements constituting the wiring structure to be manufactured, a surface facing the support substrate (SP) is also referred to as a “lower surface,” and a surface facing the opposite side with respect to the support substrate (SP) is also referred to as an “upper surface.”

As illustrated in FIG. 5B, a conductor layer 22 including multiple conductor pads (22p) is formed on the support substrate (SP). In the formation of the conductor layer 22, for example, a resist film (not illustrated) is formed on the metal film layer (ML2). A plating resist is formed by forming openings in a resist film corresponding to formation regions of the conductor pads (22p) by photolithography. A plating film is formed in the openings of the plating resist by electrolytic plating using the metal film layer (ML2) as a power feeding layer. After that, the plating resist is removed. The conductor layer 22 as illustrated in FIG. 5B is obtained.

In FIG. 5B, as well as FIGS. 5C, 5F, and 5I to 5L to be referred to below, only one surface side of the support substrate (SP) is illustrated for a state after each process, and a state of the other surface side is omitted. However, on the surface of the support substrate (SP) on the side where illustration is omitted, insulating layers and conductor layers may be formed in the same manner as on the illustrated side, or it is also possible that such conductor layers and insulating layers are not formed.

An insulating layer 31 covering the conductor layer 22 is formed. The insulating layer 31 is formed, for example, from a thermosetting resin such as an epoxy resin, a BT resin, or a phenol resin, and a thermoplastic resin such as a fluorine resin or LCP (liquid crystal polymer). The insulating layer 31 is formed by thermocompression bonding these resins molded into a film-like shape. In the insulating layer 31, through holes (11d) are formed at positions where the via conductors (11c) (see FIG. 51) are to be formed, for example, by irradiation with CO2 laser, excimer laser, or the like. Although not illustrated, the formation of the through holes (11d) may be performed while protecting the upper surface of the insulating layer 31 with a protective film such as a polyethylene terephthalate (PET) film. Preferably, after the formation of the through holes (11d), resin residues (smear) that are like to occur in the through holes (11d) are removed by dry desmearing using a plasma gas or wet desmearing using a permanganate solution.

After the formation of the through holes (11d), multiple wiring patterns 2 (see FIG. 51) formed in parallel are formed on the surface (31a) of the insulating layer 31 through the processes illustrated in FIGS. 5B to 51. First, as illustrated in FIG. 5B, a metal film (2a) is formed by sputtering on inner walls of the through holes (11d) and on the surface (31a) of the insulating layer 31. By using sputtering, it may be possible that a metal film (2a) having a small and uniform thickness can be easily formed. It is also possible that the metal film (2a) is formed using a method other than sputtering, such as electroless plating.

In the formation of the multiple wiring patterns 2, as illustrated in FIGS. 5C to 5F, multiple resist walls 4 (see FIG. 5F) formed in parallel are formed on the surface (31a) of the insulating layer 31 via the metal film (2a). In the formation of the multiple resist walls 4, first, as illustrated in FIG. 5C, a photosensitive resist layer 40 is formed on the surface (31a) of the insulating layer 31 via the metal film (2a). The resist layer 40 is a plating resist that functions against deposition of plating metal. The resist layer 40 is formed, for example, by laminating a dry film containing a photosensitive epoxy resin on the metal film (2a).

Then, by performing exposure and development on the resist layer 40, openings (4a) (see FIG. 5E) are formed in the resist layer 40. The exposure of the resist layer 40 is preferably performed by direct imaging, as illustrated in FIG. 5C. That is, without using an exposure mask, laser (LZ) is directly irradiated onto the resist layer 40 along patterns corresponding to the multiple wiring patterns 2 (see FIG. 5I). In direct imaging, since a focal depth of the laser (LZ) is relatively deep, influence of unevenness of the surface (31a) of the insulating layer 31 on the exposure of the resist layer 40 is minimal. In addition, in direct imaging, a position in the Z direction where the laser (LZ) is focused can be adjusted according to an irradiation position of the laser (LZ). Therefore, it may be possible that fine openings can be formed in the resist layer 40. Further, in direct imaging, compared to a case where an exposure mask is used, it may be possible that a wide region is exposed in a single exposure process. For example, in manufacturing a wiring substrate having a rectangular planar shape with each side measuring 80 mm to 240 mm, it may be possible that openings are efficiently formed in the resist layer 40.

In the exposure of the resist layer 40 by direct imaging, as illustrated in FIG. 5D, laser (LZ) is sequentially irradiated onto regions of the resist layer 40 where the openings (4a) (see FIG. 5E) are to be formed (opening formation regions (4b)). That is, FIG. 5D illustrates an example where exposure is performed on a positive-type resist layer 40 whose solubility in a developing solution increases due to exposure. In FIG. 5D, low-density dot hatching applied to the resist layer 40 indicates a portion where the solubility has increased due to exposure. In FIGS. 5D, 5E, 5G, and 5H, only a region where four wiring patterns 20 (see FIG. 5H) are formed is illustrated in an enlarged manner.

In the exposure of the positive-type resist layer 40, by focusing the laser (LZ) at a desired position in a thickness direction of the resist layer 40, that is., the thickness direction (Z direction) of the wiring substrate being manufactured, a range that reacts to the exposure around that position can be enlarged. That is, a region where the solubility increases around a specific position in the Z direction can be made larger than regions around other positions where the laser (LZ) is not focused. Therefore, by focusing the laser (LZ) at a central portion in the thickness direction of the resist layer 40, as illustrated in a leftmost opening formation region (4b) in FIG. 5D, a region in the resist layer 40 where the solubility increases can be made larger at the central portion in the Z direction than at both end portions in the Z direction. In this way, the exposure of the resist layer 40 may include converging the light used for the exposure, such as the laser (LZ), at the central portion in the thickness direction of the resist layer 40.

After the exposure of the resist layer 40, that is, after the irradiation of the laser (LZ) onto the opening formation regions (4b), the portions of the resist layer 40 where the solubility has increased due to the exposure are removed, for example, by development using an alkaline solution. As a result, as illustrated in FIGS. 5E and 5F, the multiple resist walls 4 formed in parallel are formed via the openings (4a). By performing the exposure as described with reference to FIG. 5D, the resist walls 4 are formed, each having a width (W1) at an end portion 41 on the insulating layer 31 side in a height direction (the Z direction) that is larger than a width (W) at a central portion in the Z direction. Since each of the resist walls 4 has the width (W1) at the end portion 41 on the insulating layer 31 side that is larger than the width (W) at the central portion, even when the width (W) at the central portion is fine, a contact area between each resist wall 4 and the metal film (2a) is relatively large, and thus it is thought that collapse or peeling of the resist wall 4 is unlikely to occur.

In this way, in the method for manufacturing the wiring substrate of the embodiment, the forming of the multiple resist walls 4 includes forming the resist walls 4 each having the width (W1) at the end portion 41 on the insulating layer 31 side in the Z direction that is larger than the width (W) at the central portion. The forming of the multiple resist walls 4 may further include forming a positive-type photosensitive resist layer 40 on the surface (31a) of the insulating layer 31 and patterning at least a portion of the resist layer 40 into the multiple resist walls 4. By forming a photosensitive resist layer 40, multiple openings and multiple resist walls 4 adjacent to each other via the individual openings can be easily formed. Further, by forming a positive-type resist layer 40, it may be possible to easily form the resist walls 4 each having the width (W1) at the end portion 41 on the insulating layer 31 side that is larger than the width (W) at the central portion in the Z direction.

In the example of FIG. 5E, each resist wall 4, which has the width (W1) at the end portion 41 on the insulating layer 31 side in the Z direction that is larger than the width (W) at the central portion, has a width at both end portions in the height direction of the resist wall 4 that is larger than the width at the central portion. Therefore, in the example of FIG. 5E, each resist wall 4 has a constriction at the central portion in the height direction of the resist wall 4.

Unlike the example of FIG. 5E, in the method for manufacturing the wiring substrate of the embodiment, it is also possible that each resist wall 4 is formed that has a width at the end portion 41 on the insulating layer 31 side in the Z direction that is larger than the width at the central portion, but has substantially the same width as the central portion at the end portion on the opposite side with respect to the end portion 41. For example, in the exposure by direct imaging described with reference to FIGS. 5C and 5D, the laser (LZ) used for the exposure may be focused across the entire range from the central portion to the upper surface of the resist layer 40 in the thickness direction. By doing so, it may be possible to form resist walls 4 each having substantially the same width as the central portion at the end portion on the opposite side with respect to the end portion 41. Even in this case, since the contact area between each resist wall 4 and the metal film (2a) at the end portion 41 is relatively large, it is thought that collapse or peeling of the resist wall 4 is unlikely to occur.

Further, in FIG. 5E, each of all the resist walls 4 has the width (W1) at the end portion 41 on the insulating layer 31 side that is larger than the width (W) at the central portion. However, in the formation of the multiple resist walls 4, it is also possible that only one resist wall 4 is formed that has the width (W1) at the end portion 41 on the insulating layer 31 side that is larger than the width (W) at the central portion.

Further, in the method for manufacturing the wiring substrate of the embodiment, it is also possible that the metal film (2a) is not provided, and the resist layer 40 is formed directly on the surface (31a) of the insulating layer 31. Therefore, the resist walls 4 may be formed directly on the surface (31a) of the insulating layer 31.

As the multiple resist walls 4, preferably, two or more resist walls are formed that are positioned at a fine pitch and each of which has a height with a large ratio relative to its width. When such resist walls 4 are formed, it may be possible to form fine wiring patterns 20 having low conductor resistance. For example, as the multiple resist walls 4, two or more resist walls each having a width (W) of 3 μm or less may be formed. Further, as the multiple resist walls 4, resist walls, each of which has a ratio of its height (H) to its width (W) of 3 or more, may be formed, and further, resist walls having an inter-wall distance (G) of 3 μm or less may be formed.

The “width” of each of the multiple resist walls 4, when a position in the Z direction is not specified, is a smallest width at any position between one end and the other end of the resist wall 4 in the Z direction. For example, the width of each resist wall 4 may be a width of the resist wall 4 at its center in the Z direction. On the other hand, the “inter-wall distance” of the multiple resist walls 4 is a largest inter-wall distance of the resist walls 4 at any position between one end and the other end of each resist wall 4 in the Z direction. For example, the inter-wall distance (G) of the resist walls 4 may be an inter-wall distance of the resist walls 4 at the center in the Z direction of the resist walls 4.

As illustrated in FIG. 5F, in addition to the multiple resist walls 4 and the openings (4a) interposed between the resist walls 4, openings (4c) and resist walls (4d) for forming conductor patterns of the conductor layer 21 (see FIG. 5I) are also formed.

After the formation of the resist walls 4, as illustrated in FIG. 5G, the plating film (2b) is formed in the openings (4a) between the multiple resist walls 4 formed in parallel. The plating film (2b) is formed by pattern plating using the resist layer 40 as a mask.

When the metal film (2a) has been formed as illustrated in FIG. 5G, the plating film (2b) is preferably formed by electrolytic plating using the metal film (2a) as a power feeding layer. Although not illustrated in FIG. 5G, the plating film (2b) is also formed in the openings (4c) (see FIG. 5F) in addition to the openings (4a) of the resist layer 40, and conductor patterns such as the via conductors (11c) (see FIG. 51) are formed.

After the formation of the plating film (2b), the resist layer 40, including the resist walls 4, is removed, for example, using an alkaline stripping solution. Further, a portion of the metal film (2a) exposed by the removal of the resist layer 40 is removed, for example, by quick etching.

As a result, as illustrated in FIGS. 5H and 5I, the conductor layer 21 including the multiple wiring patterns 2 is formed. The via conductors (11c) penetrating the insulating layer 31 are also formed. The multiple wiring patterns 2 formed of the wiring patterns 20 that are separated from each other and formed in parallel. The wiring patterns 20 are each composed of a metal film (2a) and a plating film (2b). Each wiring pattern 20 has a width (L1) at the end portion (20a) on the insulating layer 31 side that is smaller than the width (L) at the central portion in the Z direction.

As illustrated in FIG. 5J, using methods similar to the methods for forming the insulating layer 31, the conductor layer 21, and the via conductors (11c) described above, a desired number of insulating layers 31 and conductor layers 21 (three layers each in FIG. 5J), as well as via conductors (11c) penetrating the respective insulating layers, are further formed. Then, an insulating layer 32 is formed on the already formed insulating layers 31 and conductor layers 21, for example, using a method similar to the method for forming the insulating layers 31. Further, a conductor layer 23 may be formed on a surface of the insulating layer 32, for example, using a semi-additive method. Further, via conductors (11c) penetrating the insulating layer 32 are formed together with the conductor layer 23.

As illustrated in FIG. 5K, the build-up layer 12 is formed. That is, a desired number of insulating layers (12a) and conductor layers (12b) are alternately laminated on the conductor layer 23 and the insulating layer 32. In FIG. 5K, three sets of insulating layers (12a) and conductor layers (12b) are laminated. In each insulating layer (12a), via conductors (12c) are formed connecting the conductor layers above and below the insulating layer (12a). The insulating layers (12a) are formed, for example, using a method similar to the method for forming the insulating layers 31 described above. In the formation of the insulating layers (12a), instead of a film-like resin, a sheet-like resin containing a core material, such as a prepreg, may be used. The conductor layers (12b) and the via conductors (12c) are formed using any method, for example, using a semi-additive method.

The build-up layer 13 is formed on the uppermost insulating layer (12a) and conductor layer (12b) of the build-up layer 12. First, the insulating layer (13a) is formed using a method similar to that for the insulating layers (12a). In the example of FIG. 5K, the insulating layer (13a) is formed using a prepreg that contains, for example, a core material (13aa) composed of glass fiber. A prepreg with copper foil may also be used. In the insulating layer (13a), through-holes are formed by laser irradiation or drilling at positions where the via conductors (13c) are to be formed. Then, the conductor layer (13b) is formed on the surface of the insulating layer (13a), and the via conductors (13c) are formed in the through-holes of the insulating layer (13a). The conductor layer (13b) and the via conductors (13c) are formed using any method, for example, using an appropriate method such as a semi-additive method or a subtractive method.

After the formation of the build-up layer 13, the solder resist layer 14 is formed on the surfaces of the insulating layer (13a) and the conductor layer (13b) using a photosensitive epoxy resin or polyimide resin. Then, the openings (14a) defining the conductor pads (13p) are formed by photolithography.

As illustrated in FIG. 5L, the core layer (GS) of the support substrate (SP) is removed. The lower surface of the metal film layer (ML2) beneath the conductor pads (22p) is exposed. In the removal of the support substrate (SP), for example, the adhesive layer (AL) is softened by laser irradiation, and then, the metal film layer (ML2) is peeled off from the adhesive layer (AL). Then, the metal film layer (ML2) is removed by etching, exposing the lower surfaces of the conductor pads (22p) and the lower surface of the insulating layer 31. The wiring substrate (1b) illustrated in FIG. 4 is completed.

The wiring substrate of the embodiment is not limited to those having the structures illustrated in the drawings and those having the structures, shapes, and materials exemplified herein. As described above, the wiring substrate of the embodiment can have any laminated structure. The wiring substrate of the embodiment can have any number of conductor layers and insulating layers. Each conductor layer may include any conductor patterns other than multiple wiring patterns. The multiple wiring patterns do not need to be provided in all conductor layers, and the surface of the wiring substrate of the embodiment does not need to be a component mounting surface. The insulating layers (12a) and the insulating layer (13a) may be thinner than the insulating layers 31, and the conductor layers (12b) and the conductor layer (13b) may be thinner than the conductor layers 21.

The method for manufacturing the wiring substrate of the embodiment is not limited the method described with reference to the drawings. For example, the methods for forming the insulating layers or the conductor layers are not limited to the methods described with reference to FIGS. 5A to 5L. The exposure of the resist layer may be performed using an exposure mask having openings corresponding to the multiple wiring patterns. Each conductor layer may be formed using a method other than the semi-additive method, such as a full-additive method. Each insulating layer can be formed using a resin in any form without being limited to a film-like resin. In the method for manufacturing the wiring substrate of the embodiment, it is also possible that any process other than the processes described above is added, or some of the processes described above are omitted.

Japanese Patent Application Laid-Open Publication No. 2020-136646 describes a printed wiring board having circuit patterns with a relationship (L/S) between a wiring width (L) and an inter-wiring distance (S) of (3 to 15 μm)/(3 to 15 μm). In Japanese Patent Application Laid-Open Publication No. 2020-136646, when resist patterns used to form fine wirings are formed by exposure and development, an increase in widths of the resist patterns is suppressed by suppressing a proportion of diffused light during the exposure. Further, to suppress the proportion of the diffused light, substantially conical protrusions are formed on a surface of a metal layer (seed layer) underlying the resist patterns.

In the printed wiring board and its manufacturing method described in Japanese Patent Application Laid-Open Publication No. 2020-136646, it may be possible that the resist patterns cannot maintain an appropriate state during wiring formation, and wirings with fine wiring rules, such as those below 3 μm, cannot be provided. Further, it is thought that a longer plating time than usual is required to form the substantially conical projections on the surface of the metal layer (seed layer).

A wiring substrate according to an embodiment of the present invention includes an insulating layer; and a conductor layer that is laminated on a surface of the insulating layer and includes multiple wiring patterns formed in parallel. The multiple wiring patterns include wiring patterns having an inter-pattern distance of 3 μm or less, and at least one wiring pattern among the multiple wiring patterns has a width at its end portion on the insulating layer side in a lamination direction of the insulating layers and the conductor layers that is smaller than a width at its central portion in the lamination direction.

A method for manufacturing a wiring substrate according to an embodiment of the present invention includes forming an insulating layer; and forming multiple wiring patterns formed in parallel on a surface of the insulating layer. The forming of the multiple wiring patterns includes forming multiple resist walls formed in parallel on the surface of the insulating layer; and forming a plating film between the multiple resist walls formed in parallel. The forming of the multiple resist walls includes forming at least one resist wall having a width at an end portion on the insulating layer side in a height direction of each of the multiple resist walls that is greater than a width at a central portion in the height direction.

According to an embodiment of the present invention, it is thought that the resist patterns can be stable during wiring formation, and the wiring substrate can be provided with fine wirings. Further, it may be possible that fine wiring patterns can be easily formed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating layer; and
a conductor layer laminated on a surface of the insulating layer and including a plurality of wiring patterns such that the wiring patterns are formed in parallel,
wherein the plurality of wiring patterns includes a plurality of wiring patterns having an inter-pattern distance of 3 μm or less such that at least one of the wiring patterns having the inter-pattern distance of 3 μm or less has a width at an end portion on an insulating layer side that is smaller than a width at a central portion in a lamination direction of the insulating layer and the conductor layer.

2. The wiring substrate according to claim 1, wherein the plurality of wiring patterns includes a wiring pattern having an aspect ratio of 2 or more.

3. The wiring substrate according to claim 1, wherein the at least one wiring pattern has a second end portion on an opposite side with respect to the end portion on the insulating layer side in the lamination direction such that a width of the second end portion is smaller than the width at the central portion.

4. The wiring substrate according to claim 3, wherein the at least one wiring pattern has a side surface that is curved such that the side surface is bulging outward at the central portion.

5. The wiring substrate according to claim 1, wherein the conductor layer includes a metal film formed in contact with the surface of the insulating layer and a plating film formed in contact with the metal film such that a side surface of a portion of each of the wiring patterns comprising the plating film has an arithmetic mean roughness Ra in a range of 0.01 μm to 0.2 μm.

6. The wiring substrate according to claim 5, wherein the metal film is a sputtering film.

7. The wiring substrate according to claim 1, further comprising:
an upper insulating layer formed on the insulating layer such that the upper insulating layer is covering the conductor layer and filling spaces between the wiring patterns and that each portion of the upper insulating layer between the wiring patterns is constricted at a central portion in the lamination direction.

8. The wiring substrate according to claim 2, wherein the at least one wiring pattern has a second end portion on an opposite side with respect to the end portion on the insulating layer side in the lamination direction such that a width of the second end portion is smaller than the width at the central portion.

9. The wiring substrate according to claim 8, wherein the at least one wiring pattern has a side surface that is curved such that the side surface is bulging outward at the central portion.

10. The wiring substrate according to claim 2, wherein the conductor layer includes a metal film formed in contact with the surface of the insulating layer and a plating film formed in contact with the metal film such that a side surface of a portion of each of the wiring patterns comprising the plating film has an arithmetic mean roughness Ra in a range of 0.01 μm to 0.2 μm.

11. A method for manufacturing a wiring substrate, comprising:
forming an insulating layer; and
forming a plurality of wiring patterns such that the wiring patterns are formed in parallel on a surface of the insulating layer,
wherein the forming of the wiring patterns includes forming a plurality of resist walls in parallel on the surface of the insulating layer, and forming a plating film between the resist walls in parallel, and the forming of the resist walls includes forming at least one resist wall having a width at an end portion on an insulating layer side in a height direction of each of the resist walls such that the width at the end portion is greater than a width at a central portion in the height direction.

12. The method for manufacturing a wiring substrate according to claim 11, wherein the at least one resist wall has a width at both end portions in the height direction that is greater than the width at the central portion.

13. The method for manufacturing a wiring substrate according to claim 12, wherein the at least one resist wall has a constriction at the central portion in the height direction.

14. The method for manufacturing a wiring substrate according to claim 11, wherein the forming of the resist walls includes forming a resist wall having a width of 3 μm or less.

15. The method for manufacturing a wiring substrate according to claim 14, wherein the forming of the resist walls includes forming a resist wall having a height to width ratio of 3 or more.

16. The method for manufacturing a wiring substrate according to claim 14, further comprising:
forming a metal film on the surface of the insulating layer such that the resist walls are formed on the surface of the insulating layer via the metal film.

17. The method for manufacturing a wiring substrate according to claim 14, wherein the forming of the resist walls includes forming a photosensitive resist layer on the surface of the insulating layer, and patterning at least a portion of the resist layer into the resist walls, and the patterning includes exposing the resist layer by direct imaging.

18. The method for manufacturing a wiring substrate according to claim 17, wherein the resist layer comprises a positive-type photosensitive resist layer.

19. The method for manufacturing a wiring substrate according to claim 18, wherein the exposing of the resist layer includes focusing light for the exposure at a central portion of the resist layer in a thickness direction of the resist layer.

20. The method for manufacturing a wiring substrate according to claim 17, further comprising:
forming a metal film on the surface of the insulating layer such that the resist layer is formed on the surface of the insulating layer via the metal film.
